(19) United States
(12) Patent Application Publication
(10) Pub. No.: US 2009/0115425 A1
(43) Pub. Date: May 7, 2009

(54) Drive System and Method for Final Testing of an Electronic Domestic Appliance and Electronic Domestic Appliance Having the Drive System

(75) Inventor: Stefan Zeh, Wangen (DE)

Correspondence Address: LERNER GREENBERG STEMER LLP, P O BOX 2480, HOLLYWOOD, FL, 33022-2480, US

(73) Assignee: DIEHL AKO STIFTUNG & CO. KG, Wangen (DE)

(21) Appl. No.: 12/272,391

(22) Filed: Nov. 17, 2008

Related U.S. Application Data
(63) Continuation of application No. PCT/EP2007/004049, filed on May 8, 2007.

(30) Foreign Application Priority Data
May 16, 2006 (DE) 10 2006 023 094.9
Dec. 9, 2006 (DE) 10 2006 058 101.6

(51) Int. Cl. G01R 27/00; H02P 7/00; G01L 3/00; G01R 31/02

(52) U.S. Cl. 324/511; 318/490; 73/862.08

(57) ABSTRACT

A drive system is provided for an electronic domestic appliance, for example a washing machine, a dryer or a dishwasher, having an electric motor and a motor controller for controlling operation of the electric motor. The motor controller is provided with a testing device which contains at least one apparatus for measuring motor currents of the electric motor, an apparatus for applying voltages to motor terminals of the electric motor, and an interface to an evaluation apparatus. The drive system can be tested without problems and at minimal cost during final testing of the domestic appliance if the drive system is fully integrated in the domestic appliance. A method for final testing of an electronic domestic appliance having a drive system and an electronic domestic appliance having the drive system, are also provided.

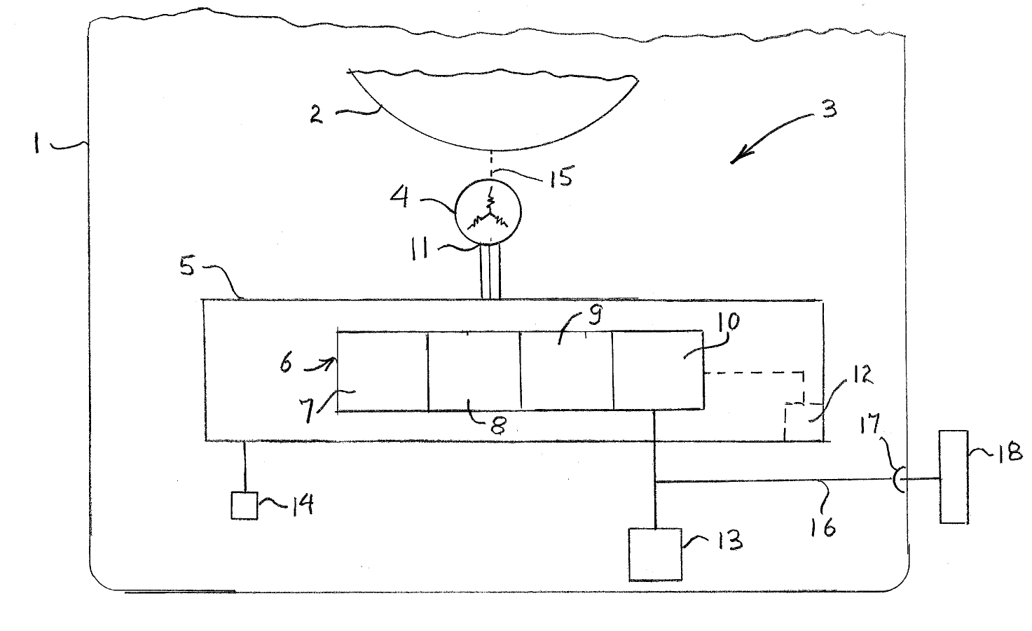

### CROSS-REFERENCE TO RELATED APPLICATIONS

This is a continuing application, under 35 U.S.C. § 120, of copending International Application No. PCT/EP2007/004049, filed May 8, 2007, which designated the United States; this application also claims the priority, under 35 U.S.C. § 119, of German Patent Application Nos. DE 10 2006 023 094.9, filed May 16, 2006, and DE 10 2006 058 101.6, filed Dec. 9, 2006; the prior applications are herewith incorporated by reference in their entirety.

### BACKGROUND OF THE INVENTION

### Field of the Invention

The present invention relates to a drive system for an electronic domestic appliance, for example a washing machine, a dryer or a dishwasher. The invention also relates to a method for final testing of an electronic domestic appliance and an electronic domestic appliance having the drive system.

The drive system is defined herein in the case of washing machines and dryers as the combination of the components: electric motor, motor controller, belt, belt pulley, washing drum, bearing, seal and cable harness between the motor controller and the electric motor. The belt and belt pulley are dispensed with in washing machines and dryers with a direct drive. For dishwashers, the drive system is defined as the combination of the electric motor, motor controller, cable harness and pump housing of the circulation pump.

The components: electric motor, motor controller and cable harness are conventionally tested themselves and installed in the end device during assembly of that end device. Final testing of a device includes brief operation of the device with standard movements like those occurring during useful operation. In this case, certain parameters such as direction of rotation, rotational speed and consumed power are checked. To that end, an external measuring device which has to be synchronized with the motor controller is required.

The electrical variables of the drive system are not usually recorded during such final testing operations. Although it is feasible to connect an external test unit, such a contact-making operation is very complicated since the measurement points of the drive system within the end device are difficult to access.

In the case of a direct drive, the most favored manner of production to date has been to deliver the stator and rotor of the electric motor in a pretested state and then to mount them on the tub of the washing machine or of the dryer or tumble dryer. In that case, the bearing of the washing drum is also the bearing of the electric motor. In that manner of production, the rotary movement of the electric motor can be tested only after the electric motor is installed in the domestic appliance. That again requires complicated contact-making with the electric motor within the end device.

### SUMMARY OF THE INVENTION

It is accordingly an object of the invention to provide a drive system and a method for final testing of an electronic domestic appliance as well as an electronic domestic appliance having the drive system, which overcome the hereinafore-mentioned disadvantages of the heretofore-known systems, methods and appliances of this general type and in which the drive system can be tested in a simple and cost-effective manner during final testing of the domestic appliance.

With the foregoing and other objects in view there is provided, in accordance with the invention, a drive system for an electronic domestic appliance. The drive system comprises an electric motor having motor terminals, and a motor controller for controlling operation of the electric motor. The motor controller has a testing device (integrated in or in one piece with the motor controller) containing an apparatus for measuring motor currents of the electric motor, an apparatus for applying voltages to the motor terminals of the electric motor, and an interface to an evaluation apparatus.

With the objects of the invention in view, there is also provided a method for final testing of an electronic domestic appliance having a drive system with an electric motor and a motor controller for controlling operation of the electric motor. The method comprises applying voltages to motor terminals of the electric motor with the motor controller and measuring corresponding motor currents of the electric motor, and communicating measurement data to an evaluation apparatus for testing the drive system installed in the domestic appliance.

Since a testing device which is suitable for testing the drive system is integrated in or is part of the motor controller, the test processes can be moved to the motor controller, and therefore testing of the drive system during final testing of the domestic appliance, that is to say with the drive system installed in the end device, is possible without problems and without external test units having to perform complicated operations to make contact with measurement points which are difficult to access. The time and cost outlay for testing can therefore be reduced overall. In addition, the drive system can be tested for possible additional faults which cannot be established during preliminary testing of the individual components.

In contrast to the invention specified above, the conventional motor controllers do not contain any dedicated test functionality and only those movement sequences which are required for normal operation of the respective domestic appliance are implemented.

In accordance with another feature of the invention, the testing device preferably also contains an apparatus for measuring motor voltages of the electric motor in order to extend testing and evaluation options.

In accordance with a further feature of the invention, the measurement data recorded by the testing device can be communicated, for example, from the motor controller to an external test unit through the interface of the testing device. The external test unit then evaluates the measurement data and displays the corresponding result to a user. A serial interface which is usually readily implemented in the motor controller is suitable, for example, for communicating the measurement data.

In accordance with an added feature of the invention, as an alternative, the motor controller can also have its own evaluation apparatus in order to be able to evaluate the measurement data itself. The evaluation result can be passed from the motor controller, for example through the use of an LED display, to the user or be communicated to the user by a characteristic movement profile of the drive system. For example, the motor controller can be increased to a high rotation speed of the electric motor when there is a positive evaluation result, in which case an additional noise level assessment is then performed by external measurement devices, or remain at a standstill when there is a negative evaluation result.

The above-described drive system or method can advantageously be used in electronic domestic appliances, such as washing machines, dryers, tumble dryers and dishwashers, for simple testing of the drive system in the end device.

The motor controller contains at least one device for measuring motor currents and for applying voltages to the motor terminals of the electric motor. A device for measuring the motor voltages is also preferably provided.

After the motor controller is switched on during final testing of the domestic appliance, the motor controller tests various drive parameters. After being enabled by the main controller of the domestic appliance or at the instigation of the main controller, special movement sequences are also run through, with which specific parameters can be determined more accurately than in the case of standard movements in the conventional final testing operations mentioned in the introduction.

In accordance with an additional feature of the invention, the parameters of the drive system in question and their measurement methods are as follows, noting that it goes without saying that the following list is only exemplary and, in particular, is not to be understood as being exhaustive:

Stator Resistance

The stator resistance between at least two motor terminals of the electric motor is established by applying DC voltage and calculating the quotient of voltage to current. In this case, the average value or integral is advantageously formed over a certain period of time of up to a few seconds.

Stator Inductance

The stator inductance between at least two motor terminals of the electric motor is established by applying brief voltage pulses and measuring the change in current when the voltage changes, or determining the voltage/time integral by integrating the voltage and current signals with respect to time.

Rotor Position-Dependent Stator Inductances

Rotor position-dependent stator inductances, as occur, for example, in reluctance motors or permanent-magnet synchronous motors, are established by measuring the stator inductance in the various directions (d and q direction) by applying voltage pulses in the various directions.

Motor Symmetry

In polyphase electric motors, the motor symmetry can be established by determining the stator resistance in various directions of the space vector for voltage and current. If necessary, this can also be performed by determining the stator inductance in various directions of the space vector for voltage and current.

Contacts of the Cable Harness

The soundness of the electrical contacts of the cable harness between the motor controller and electric motor is automatically ensured when the stator resistance and the motor symmetry are established.

Magnetic Flux

The magnetic flux of the permanent magnet (in the case of a permanent-magnet motor) is determined by testing the strength and the symmetry of a flux during operation of the electric motor at a constant rotational speed. As an alternative, the electric motor can also be revved up and the induced voltages (=EMF) during ramping can be measured, with the amplitude, symmetry and DC component of the EMF being evaluated.

Rotor Time Constant

The rotor time constant in an asynchronous motor can be determined from the jump response of the motor current to a voltage jump.

Consumed Power and Torque

The motor controller should also be able to establish the operating power and the torque of the electric motor. As a result, unbalances and mechanical faults can be detected. An acceleration attempt can be used to establish the inertia of the system, this in turn providing conclusions about the soundness of assembly. If a sound seal and a sound machine bearing are provided, the frictional power has to lie within certain limits.

Belt Test

A belt which is not (correctly) applied is noticeable due to incorrect inertia of the drive system. Excessive belt tension may possibly be identified by excessive friction. When there is a strong acceleration movement together with a torque which is used with higher dynamics than in the case of standard movements, an excessively high or excessively low belt tension can be detected through the use of the resulting rotational speed profile.

It goes without saying that the tests listed above can also be used to test the functioning of the electronic motor controller itself. As a result, separate tests may be dispensed with during final production of the motor controller, and this further reduces system costs.

Other features which are considered as characteristic for the invention are set forth in the appended claims.

Although the invention is illustrated and described herein as embodied in a drive system and a method for final testing of an electronic domestic appliance as well as an electronic domestic appliance having the drive system, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

The FIGURE of the drawing is a block diagram of an electronic domestic appliance having a drive system according to the invention.

### DETAILED DESCRIPTION OF THE INVENTION

Referring now in detail to the single FIGURE of the drawing, there is seen an electronic domestic appliance 1, for example a washing machine, a dryer or a dishwasher, having a drum 2 and a drive system 3. The drive system 3 includes an electric motor 4 and a motor controller 5 for controlling operation of the electric motor 4. Reference numeral 15 represents a belt drive or a direct drive between the electric motor 4 and the drum 2. The motor controller 5 has a testing device 6 (integrated in or in one piece with or part of the motor controller 5), containing an apparatus 7 for measuring motor currents of the electric motor 4, an apparatus 8 for applying voltages to motor terminals 11 of the electric motor 4, an apparatus 9 for measuring, estimating or calculating motor voltages of the electric motor 4 from measured DC bus voltage and pulse patterns of the power stage and an interface 10 connected to an evaluation apparatus 13. Measurement data recorded by the testing device 6 can be communicated, for example, from the motor controller 5 to an external test unit 18 through the interface 10 of the testing device 6, a line 16 and a port 17. As an alternative, the motor controller 5 can also have its own evaluation apparatus 12 in order to be able to evaluate the measurement data itself. The evaluation result can be passed from the motor controller 5, for example through the use of an LED display 14, to the user or be communicated to the user by a characteristic movement profile of the drive system 3.

1. A drive system for an electronic domestic appliance, the drive system comprising:
an electric motor having motor terminals; and
a motor controller for controlling operation of said electric motor, said motor controller having a testing device containing an apparatus for measuring motor currents of said electric motor, an apparatus for applying voltages to said motor terminals of said electric motor, and an interface to an evaluation apparatus.

2. The drive system according to claim 1, wherein said testing device also contains an apparatus for measuring motor voltages of said electric motor.

3. The drive system according to claim 1, wherein said interface of said testing device is configured to communicate with an external test unit.

4. The drive system according to claim 1, wherein said evaluation apparatus is also integrated in said motor controller.

5. The drive system according to claim 1, wherein said evaluation apparatus is configured to determine and evaluate at least one of the following parameters:
stator resistance between at least two of said motor terminals of said electric motor;
stator inductance between at least two of said motor terminals of said electric motor;
rotor position-dependent stator inductances;
motor symmetry (in polyphase electric motors);
electrical contacts of a cable harness between said motor controller and said electric motor;
magnetic flux of a permanent magnet (in a permanent-magnet motor);
rotor time constant (in an asynchronous motor);
consumed power;
consumed torque;
mass inertia of the system; or
parameters of a belt (in a belt drive).

6. An electronic domestic appliance, comprising a drive system according to claim 1.

7. A method for final testing of an electronic domestic appliance having a drive system with an electric motor and a motor controller for controlling operation of the electric motor, the method comprising the following steps:
applying voltages to motor terminals of the electric motor with the motor controller and measuring corresponding motor currents of the electric motor; and
communicating measurement data to an evaluation apparatus for testing the drive system installed in the domestic appliance.

8. The method according to claim 7, which further comprises additionally measuring motor voltages of the electric motor with the motor controller.

9. The method according to claim 7, which further comprises communicating the measurement data to an external test unit or to an evaluation apparatus integrated in the motor controller.

10. The method according to claim 7, which further comprises evaluating at least one of the following parameters:
stator resistance between at least two motor terminals of the electric motor;
stator inductance between at least two motor terminals of the electric motor;
rotor position-dependent stator inductances;
motor symmetry (in polyphase electric motors);
electrical contacts of a cable harness between the motor controller and electric motor;
magnetic flux of a permanent magnet (in a permanent-magnet motor);
rotor time constant (in an asynchronous motor);
consumed power;
consumed torque;
mass inertia of the system; or
parameters of a belt (in a belt drive).
